(19) United States
(12) Patent Application Publication
(10) Pub. No.: US 2013/0022756 A1
(43) Pub. Date: Jan. 24, 2013

(54) ADHESION OF METAL THIN FILMS TO POLYMERIC SUBSTRATRES

(71) Applicants: BRIAN HOWARD AUGUSTINE, BRIDGEWATER, VA (US); WILLIAM CHRISTOPHER HUGHES, HARRISONBURG, VA (US); ALAN KOON-KEE MO, GLEN ALLEN, VA (US); THOMAS CARROLL DEVORE, HARRISONBURG, VA (US)

(72) Inventors: BRIAN HOWARD AUGUSTINE, BRIDGEWATER, VA (US); WILLIAM CHRISTOPHER HUGHES, HARRISONBURG, VA (US); ALAN KOON-KEE MO, GLEN ALLEN, VA (US); THOMAS CARROLL DEVORE, HARRISONBURG, VA (US)

(21) Appl. No.: 13/553,393

(22) Filed: Jul. 19, 2012

Related U.S. Application Data
(60) Provisional application No. 61/509,863, filed on Jul. 20, 2011.
(60) Provisional application No. 61/513,334, filed on Jul. 29, 2011.

(51) Int. Cl. B05D 7/00; C23C 14/35; C25D 5/56

(52) U.S. Cl. 427/551; 427/322; 427/343; 427/241; 427/250; 427/560; 427/258; 427/261; 205/164; 204/192.12

(57) ABSTRACT

The adhesion of metal thin films onto polymeric substrates can be significantly enhanced by contacting the surface of the polymeric substrate with a non-complexing solvent before or after depositing the metal film.

### CROSS-REFERENCE TO RELATED APPLICATIONS

This application is based on and derives the benefit of the filing date of U.S. Provisional Patent Application No. 61/509,863, filed Jul. 20, 2011 and No. 61/513,334, filed Jul. 29, 2011. The entire content of these applications is herein incorporated by reference in its entirety.

### FIELD OF THE INVENTION

The present technology relates to methods of depositing metal thin films onto polymeric substrates.

### DESCRIPTION OF RELATED ART

Polymeric substrates are widely used in a variety of technologies including polymer microdevices, microfluidics, sensors, biomedical devices, flat panel displays, photovoltaic devices, micro total analysis systems (μ-TAS or “lab-on-a-chip”), and the aerospace, battery, and automotive industries. The advantages of polymeric substrates include improved manufacturability, lower processing temperatures and overall thermal budget, and lower cost of manufacture. A critical processing step needed for devices employing polymeric substrates includes the deposition of metal thin films in the fabrication of electrodes and interconnecting wires in a variety of devices including sensors, catalysts, photonics, polymer electronics, μ-TAS, and microelectrodes. Vapor deposited gold (Au) thin films are widely used in many of these technologies.

The materials properties that make Au useful include its corrosion resistance, high infrared reflectivity, and outstanding electrical and thermal conductivity (approximately 11% and 34% better than aluminum (Al), respectively). Unfortunately, Au is a relatively inert metal that has notoriously poor adhesion to polymers. Process engineers have developed extensive methods to deposit Au interconnects and electrodes in silicon-based microelectronics and microelectromechanical systems (MEMS) through the use of a vapor deposited adhesion layer. Typically, this layer is produced by deposition of a reactive metal such as chromium (Cr) or titanium (Ti), which can form a chemical bond with polar atoms on the surface. The adhesion-layer is generally thin (less than about 5 nm) and is deposited immediately prior to the Au film without breaking vacuum so that the surface of the adhesion film does not oxidize. This generally requires two deposition sources (targets, evaporation boats, etc.) in the same vacuum system. The subsequent Au film then forms an intermetallic compound at the interface between the metals with the adhesion material, and thus produces a thin film that is conformal and well bonded to the silicon (Si), silicon dioxide (SiO₂), or other inorganic substrate.

Since technologically useful polymers are largely non-polar due to the extensive hydrocarbon bonding present, there have been a variety of attempts to modify their surface chemistry making them more amenable to Au thin film deposition. Techniques which have been used to improve polymer/Au thin-film adhesion include chemical etching, corona discharge, plasma treatment, and irradiation. There is some evidence that the bonding is improved in certain polymers such as poly(methyl methacrylate) (PMMA) by the cross-linking of damaged PMMA in the subsurface region. However, most techniques have generally met with limited success in significantly improving the Au thin film adhesion onto many polymeric substrates. A major drawback of the aforementioned techniques is that they have the potential to damage the surface of the substrate.

### SUMMARY OF THE INVENTION

The present technology relates to methods of depositing metal films on polymeric substrates.

In one aspect, a method of forming a deposited metal film on a polymeric substrate is provided that includes steps of providing a polymeric substrate, contacting the polymeric substrate with a non-complexing solvent, and depositing one or more layers of metal onto the substrate. The step of contacting the polymeric substrate with the solvent can be before or after the step of depositing.

### BRIEF DESCRIPTION OF THE DRAWINGS

Specific examples have been chosen for purposes of illustration and description, and are shown in the accompanying drawings, forming a part of the specification.

FIG. 1 illustrates examples of optical micrographs of 11×11 Au dot arrays on PMMA substrates, as discussed in Example 1 herein.

FIG. 2 illustrates results of tape-test adhesion trials conducted on Au dot arrays, as discussed in Example 1 herein.

FIG. 3 illustrates 30 μm×30 μm AFM images for samples, as discussed in Example 1 herein.

FIG. 4 illustrates results of tape-test adhesion trials conducted on Au dot arrays using spun-cast solvents, as discussed in Example 2 herein.

FIG. 5 illustrates tape-test adhesion results for the samples exposed to solvent vapors, as discussed in Example 2 herein.

FIG. 6 illustrates waterfall plots from evolved gas Fourier transform infrared (EGA-FTIR) spectroscopy at different temperatures, as discussed in Example 2 herein.

FIG. 7 illustrates a Van't Hoff plot of the natural log of the integrated peak intensity vs. the inverse temperature, as discussed in Example 2 herein.

FIG. 8 illustrates data from high resolution x-ray photoelectron spectroscopy (XPS) of the Cl 2p binding energy region from 190-210 eV for two types of samples, as discussed in Example 2 herein.

FIG. 9 illustrates the time evolution of the relative peak area of the Cl 2p XPS peak for a CHCl₃-PMMA sample, as discussed in Example 2 herein.

FIG. 10 illustrates high-resolution O 1s binding energy XPS data for certain samples, as discussed in Example 2 herein.

FIG. 11 illustrates representative data of the lateral force signal for the CFM study for CHCl₃-treated and as-cleaned PMMA samples, as discussed in Example 2 herein.

FIG. 12 illustrates spectroscopic evidence provided through attenuated total reflection Fourier transform infrared spectroscopy (ATR-FTIR) in which C—Cl bonding was observed up to 7 days after solvent deposition, as discussed in Example 2 herein.

FIG. 13 illustrates the relationship between the measured percent Au adhesion and the literature values for the Gutmann's acceptor number, as discussed in Example 2 herein.

FIG. 14 illustrates results of density functional theory (DFT) calculations performed on a model of the PMMA/solvent/Cr system, as discussed in Example 2 herein.

FIG. 15 illustrates results comparing spun-cast vs. vapor exposed chloroform adhesion promoter for magnetron sputter deposited and e-beam evaporated Au films onto PMMA, as discussed in Example 2 herein.

### DETAILED DESCRIPTION OF SEVERAL EMBODIMENTS

The present technology relates to methods of improving the adhesion of metal films deposited onto polymeric substrates by exposing the polymeric substrate to at least one non-complexing solvent in addition to metal deposition. The exposure can occur before or after deposition. The metal deposition for methods of the present technology can include depositing a first layer of metal, such as a layer of Cr, as an adhesion layer onto the polymeric substrate prior to depositing a second layer of metal, such as Au, or can include depositing a single metal film directly onto the polymeric substrate. Without being bound by any particular theory, it is believed that the mechanism for the improvement in metal thin film adhesion is due to the presence of residual solvent molecules that form a relatively stable hydrogen-type bond with the polymeric substrate and the metal, whether it be the atoms of the first metal layer forming an adhesion layer or the atoms of a single metal layer directly deposited onto the polymeric substrate. When exposure occurs after deposition, in addition or alternatively to the above, the exposure may reduce the stress at the metal-polymer interface. Alternatively or in addition, the post-deposition exposure may roughen the surface of the polymer on a nanometer-micrometer scale.

Methods of the present technology can be useful in several technological applications, including for example, biomedical devices including implants and biomimetic technologies, sensors, microfluidic (micro total analysis system (μ-TAS) or “lab-on-a-chip”), microelectromechanical systems (MEMS), organic flat panel displays such as organic light emitting diodes, photovoltaic devices, organic electronics, fuel cells, and batteries, and automotive coatings among others. Additionally, microfabricated metal structures such as microelectrodes, thermocouples employing the Seeback effect, resistive temperature devices (RTD), thermoelectric devices (such as a Peltier cooler) and metal interconnects such as Ohmic or Schottky barriers could all potentially be applied to polymeric substrates using methods of the present technology.

Polymeric substrates suitable for use with the present technology can be polymers, polymer blends, co-polymers, or nanocomposite (hybrid organic/inorganic) polymers. In some examples, the polymeric substrate can contain surface carbonyl, ether, hydroxyl or ester groups, or can have a non-oxygen containing surface that has been oxygenated using oxygen plasmas. Examples of polymers that contain surface carbonyl, ether, hydroxyl or ester groups include acrylic polymers, such as poly(methyl methacrylate) (PMMA), poly acrylic acid (PAA), poly(n-butyl methacrylate) (p(nBMA)), poly(tert-butyl methacrylate) (p(tBMA)), poly(allyl alcohol), poly(hydroxyethyl acrylate), and polyimides. Examples of non-oxygen containing surfaces that could be oxygenated include polyethylene, polypropylene, and polystyrene. Common polymers with an ester functionality within the main-chain backbone may also be employed, such as polyester polyethylene terephthalate (PET) or polyurethanes. These show a range of applications ranging from plastic bottles to medically implanted devices for PET and from shape memory polymers to biodegradable polymers for polyurethanes. Frequently used polymers with different, but relevant, chemistries use the Lewis acid-base adduct formed with non-complexing solvents. Polyamides (such as nylon) or polyacrylamides (such as poly N-isopropylacrylamide) have a nitrogen in place of the non-carbonyl oxygen found in esters, but function as a Lewis-base in the presence of a Lewis-acid solvent. Similarly, polythioesters (PTEs) that contain a sulfur atom in place of the non-carbonyl oxygen. All such polymers may be employed.

Solvents suitable for use with the present technology include non-complexing solvents. Non-complexing solvents include, but are not limited to, chloroform and dichloromethane and other halogenated solvents. Without being bound by any particular theory, it is believed that non-complexing solvents can form a Lewis acid-base adduct with the polymer, which may result in residual solvent molecules remaining on the surface interacting with the ester groups of the acrylic polymer after the bulk solvent has evaporated. For example, a non-complexing solvent may be able to form a Lewis acid-base interaction (non-traditional hydrogen bond) with the polymer chain, a relatively weak bond between the solvent and the polymer so that it can act as a leaving group after the metal is introduced, and the formation of a relatively strong metal halide ionic bond to enhance the metal attraction to the surface. DFT calculations and XPS data provided in the Examples below suggest that a complex may be formed between the bridging O in the PMMA and a Metal-Cl bond. Gutmann's acceptor number is believed to be a strong predictor of Cr/Au or Au adhesion. When exposure occurs after deposition, in addition or alternatively to the above, the exposure may reduce the stress at the metal-polymer interface. Alternatively or in addition, the post-deposition exposure may roughen the surface of the polymer on a nanometer-micrometer scale.

Methods of the present technology include providing a polymeric substrate, contacting the substrate with a non-complexing solvent, and then depositing one or more layers of metal onto the substrate. Alternatively, the contacting can occur after the depositing. Post-treating deposits of metal may be effective for metal layers up to 15 nanometers thick, for example, 6, 10 and 15 nanometers thick. The effect may also occur with metal layers 50 or 100 nanometers, or more in thickness.

Contacting the substrate with a non-complexing solvent can be accomplished, for example, by spin casting, vapor exposure, spray exposure, jet nebulizers, ultrasonic wave nebulizer, or dip coating. The contacting can be carried out for a suitable period of time, including for example, up to about 500 seconds. In one example spin casting, can be conducted for a time period from about 45 seconds to about 90 seconds, including about 60 seconds. In another example, vapor exposure can be conducted for a time period from about 100 seconds to about 360 seconds. With post-deposition processing, vapor deposition for a time period of 10 seconds or less may be effective.

Use of contacting methods such as vapor exposure, spray exposure, nebulizers, and dip coating can allow the use of substrates having any shape, including large sizes and three-dimensional geometries. Additionally, it is believed that vapor exposure does not result in any topological modification or damage to devices which may have been fabricated in a prior processing step. The vapor exposure technique is potentially attractive as a technology for enhancing the adhesion of metal films onto PMMA devices such as μ-TAS, photonic, or biomedical devices. Additionally, since one can treat non-planar geometry substrates, this technology could be used in the coating of high performance fibers which could then be woven into conductive cloth. Efficacy of solvent treatment for adhesion can be obtained for over one week after exposure held either under vacuum or in ambient conditions. The step of contacting the polymeric substrate with a solvent may also render the surface more receptive to deposited substances such as inks, paints, laminating adhesives, etc. since the surface is more hydrophilic and reactive.

Deposition of the one or more metal layers onto the substrate can be performed through any suitable technique, including vapor deposition, electroplating, or electroless plating. Some examples of suitable vapor deposition techniques include, but are not limited to atomic layer deposition (ALD), chemical vapor deposition (CVD), electron-beam evaporation, magnetron sputter deposition, thermal evaporation or molecular beam epitaxy (MBE) onto the solvent pre-treated fibers. Metal exposure of the polymer surface can be made onto a patterned substrate through a suitable shadow mask fabricated either through a fabricated elastomeric material such as polydimethylsiloxane (PDMS), a more conventional hard shadow mask such as a metal fabricated through lithography or electrical discharge machining (EDM), or conventional microlithography which should enable controlled regions of adhesion. This could allow for an alternative to the microfabrication of metal microstructures rather than a complicated “lift-off” process typically performed for the deposition of inert metals such as Pt and Au. For example, the step of contacting the polymeric substrate with a non-complexing solvent can include applying a spatially defined pattern of the solvent or solvent vapor to the substrate, and then metal deposited onto areas of the substrate outside the pattern of solvent can be removed. Depositing the one or more metal layers can be accomplished by applying the metal in a gas form to the substrate, provided that the deposition temperature remains below the decomposition temperature of the polymer substrate.

The one or more metal layers that can be deposited onto the substrate can include Cr, Cu, Ag, Au, Mo, W, Mn, Fe, Co, Ni, Pt, Ir, V, Ti, Zr, Ta, Nb, and combinations thereof. Coating polymer surfaces with Ag nanoparticles deposited via this adhesion promoter would render the surfaces antimicrobial. In some examples, the step of depositing one or more metal layers can include depositing a first metal layer as an adhesion layer onto the polymeric substrate, and then depositing a second metal layer onto the adhesion layer. For example, a first layer of Cr can be deposited as an adhesion layer, and then a layer of Au or Pt can be deposited onto the Cr layer. Use of a Cr adhesion layer with currently known deposition methods is the standard technique for getting Au films to adhere to silicon or glass (silica) or other inorganic substrates typically used in the semiconductor industry. In other examples, the step of depositing one or more metal layers can include depositing a single layer of metal, such as Cr, Cu, Ag, Au, Mo, W, Mn, Fe, Co, Ni, Pt, V, Ti, Zr, I-If, Ta, Nb, directly onto the polymeric substrate. Products having Au films deposited directly onto the polymeric substrate would be non-biofouling. Additionally, in some examples, eliminating the Cr adhesion layer can simplify the required metallization tool in that a deposition chamber with multiple targets is no longer required, which can reduce the cost of the metallization source and costs associated with the elimination of hazardous heavy metal materials such as Cr.

Depositing Au on a polymer and then exposing to chloroform vapor may enhance the adhesion of the Au to the polymer. The Au layer may be 6 nanometers or less, 10 nm, 15 nm, 50 nm or 100 nm or more in thickness. The polymer/Au may be exposed to chloroform vapor for a range of times, from 10 seconds or less to more than 10 seconds.

A PDMS or other type of physical mask may be placed on the surface of the metal film after deposition but prior to vapor post-exposure to define a region that will be selectively exposed to the vapor. The post-vapor treatment will only affect the exposed areas. Metal in the exposed areas will adhere to the PMMA surface while metal in the unexposed areas will not adhere. Masking of this sort may make differentially removable metal films through polishing techniques such as the chemical-mechanical polishing (CMP) process used widely in the semiconductor industry. Masking of this sort may also be employed to create patterned and conductive nanostructures with nanometer-micrometer feature sizes. Masking may also be used in conjunction with self-assembly techniques such as gold-alkanethiol chemistry to selectively and spatially modify the surface chemistry of PMMA. Masking may be employed to produce electrodes or sensors that do not require lithography or lift-off techniques. Masking may be employed to produce catalytically active surfaces using Pt nanoparticles in a defined spatial pattern.

### Example 1

### A. Substrate Preparation

Four types of samples were prepared for magnetron sputter deposition. A CO₂ laser cutter/engraver (Universal Laser Systems, Inc.) was used to cut commercially available PMMA sheet (McMaster-Carr) into 2.54 cm×2.54 cm×1 mm substrates. After laser cutting, all samples were placed in an 80° C. oven in air for 10 minutes to relieve stress from the laser cutting process. After room temperature cooling, the chips were placed in a beaker with 2-propanol (Laboratory Grade, Fischer), sonicated for 10 minutes, and dried thoroughly with compressed N₂. The first type of samples had Cr/Au thin films directly deposited onto the as-cleaned samples which are called the “control” series.

The second series of samples were exposed to a remote O₂ plasma in a March PX-250 plasma chamber. The remote plasma geometry consisted of a powered Al top electrode, a perforated Al grounded electrode located 2.54 cm below the top electrode and a floating electrode located 10 cm below the grounded electrode. A 25 W plasma was generated in an O₂:N₂ gas mixture in a 5:95 seem ratio. The samples were placed onto the floating electrode downstream from the plasma for 500 seconds. Prior work has shown that polymer films exposed to these remote plasma conditions result in primarily chemical changes caused by reactions of radical species with the surface with minimal physical sputtering or etching.

The third series of samples were spun-cast with 0.3 mL of three different organic solvents to observe how solvents with significantly different polarities affect Cr/Au adhesion to PMMA substrates. The solvents tested were hexanes (Technical Grade Naphtha Solvent, Fisher), toluene (Certified ACS, Fisher) and chloroform (Certified ACS, Fisher). The solvents were placed on the substrate and spun at 1000 rotations per minute (rpm) for 45 seconds followed by 300 rpm for 15 seconds. These samples were then placed in the metallization chamber within 10 min. of spin-casting the solvent.

The fourth series of samples (called “vacuum-stored”) were spun-cast with solvents in a manner analogous with the third series. However these samples were stored in the deposition system at the base pressure of less than about 5×10⁻⁶ torr for 96 hours prior to metal deposition. These samples were used to test whether the effect of solvent pre-treatment changed after an extended exposure to a high vacuum environment.

### B. Magnetron Sputter Deposition, Au Thin Films

Metal thin films were deposited onto PMMA samples through a shadow mask. Shadow masks consisted of an 11×11 grid of equally spaced 1.5 mm diameter circles with a 1.6 mm spacing between features. Cr/Au films were deposited via magnetron sputter deposition in an Edwards Auto 500 system at a deposition pressure of 3.0×10⁻³ torr. DC magnetron plasma conditions were created in an Ar plasma with a plasma power of 150 W and a 10 seem Ar flow rate. The sample stage was rotated during deposition to ensure a uniform deposition. The Cr adhesion layer was deposited for 30 seconds resulting in a film having a thickness of about 10 Å, and then Au was deposited for 7 minutes resulting in film having an average thickness of about of 1000 Å. Film thicknesses were measured using a stylus profilometer (Tencor Alpha Step).

### C. Materials Characterization

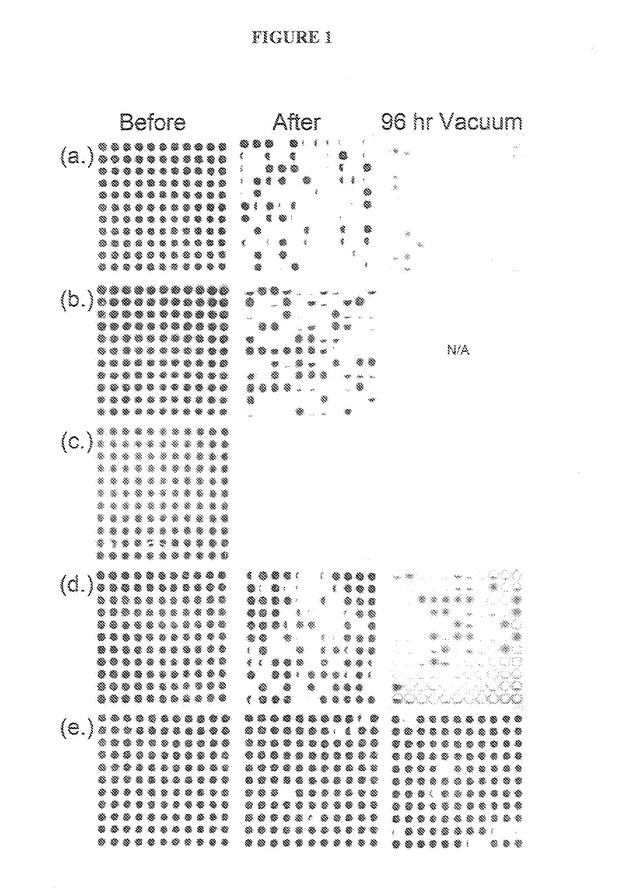

The physical adhesion of Cr/Au films onto the PMMA substrates was measured using a tape test adhesion measurement. A stereomicroscope (Leica MZ6) and a digital camera (PixeLINK PL-A781) captured images of the PMMA substrates after metal deposition. Then a 1.91 cm×2.54 cm piece of adhesive tape (3M Scotch Magic Tape) was pressed onto each chip. The tape was uniformly removed at an angle of about 10° to about 15° relative to the surface of the PMMA substrate. Any non-adhering gold dots remained on the adhesive surface of the tape. The average force applied was about 5 N for the tape-pull test as measured using a digital force gauge (Vernier Dual Range Force Sensor with LabPro interface). A second image of the PMMA substrate was then captured in the microscope after the tape was removed. All images were analyzed using Image J software. Images were first converted to 8-bit grayscale followed by thresholding to black and white to distinguish the Au film from the PMMA background. The total number of black pixels was counted for each image before and after the adhesion test. The black pixels correspond to the Au film remaining on the surface. FIG. 1 illustrates examples of optical micrographs of the 11×11 Au dot arrays on PMMA substrates. The left column illustrates samples immediately after Cr/Au deposition but before the tape-pull test. The center and right columns illustrate samples immediately after the tape-pull test, with the right column being samples that were vacuum stored for a 96 hour period prior to deposition of the metal thin films. Each Cr/Au dot in FIG. 1 has a diameter of about 1.5 mm. Images have been converted to 8-bit grayscale. Edge roughness is due to laser-cut PMMA shadow mask. The row designated as (a.) was a control series, the row designated as (b.) was remote O₂ plasma-treated, the row designated as (c.) was hexane-cast, the row designated as (d.) was toluene-cast, the row designated as (e.) was chloroform-cast.

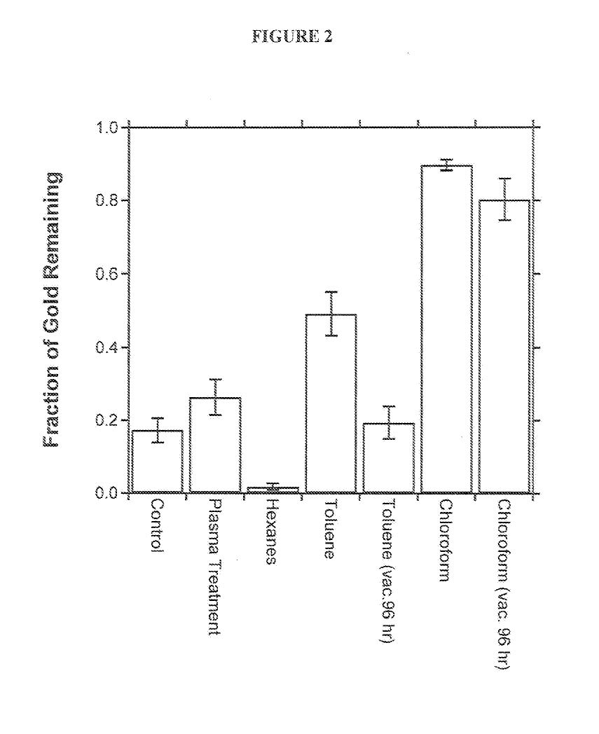

The fraction of gold remaining on each PMMA sample was determined by dividing the number of black pixels after the tape-test to the number before. The average Au remaining was determined by measuring between 7 and 32 sample arrays of each of the four series. Two-tailed unpaired t-tests statistics were used to observe differences in means of the remaining Au. The results are illustrated in FIG. 2, with the error bars being one standard deviation of the mean. The control, plasma-treated, and chloroform-treated samples had extensive tape-test trials performed on them (N=19, 15 and 32 on complete 121 dot arrays, respectively.) Other trials ranged from N=7 for the toluene-treated vacuum-stored test to N=8-11 for all other samples types. FIGS. 1 and 2 clearly show that the Cr/Au adhesion is significantly improved for the samples spun-cast with both toluene (49.2%, t=3.93×10⁻⁵) and chloroform (89.6%, t=1.06×10⁻²⁷) when compared to the control sample (17.2%). Samples treated with hexane prior to deposition showed very poor adhesion (1.8%), and samples which had received an oxygen plasma-treatment were modestly improved compared to the control samples (26.3%). This is consistent with prior literature suggesting that plasma-treatment has a limited effect on improving the adhesion of Au thin films onto polymeric substrates. It should be noted that the Au dots that remained were able to withstand a pull-force of 5 N which was the measured adhesion of the tape onto clean PMMA. No upper bound on the force required to remove the Au features was measured.

The vacuum-stored toluene-treated and chloroform-treated samples exhibited a reduction in the adhesion of the metal layers compared to the samples in which the solvent was immediately deposited as shown in FIG. 2. Surprisingly, the adhesion of the vacuum-stored chloroform samples remained relatively high (about 80%) albeit with larger error bars. The toluene sample dropped to the control level after vacuum storage. The chloroform result is particularly surprising given that the vapor pressure at 25° C. of both hexane (150.0 Torr) and chloroform (195.0 Torr) is considerably higher than that of toluene (28.5 Torr). Given the high vapor pressure of the solvents, it would be expected that any solvent on the surface would have desorbed after 96 hours at 10⁻⁶ Torr.

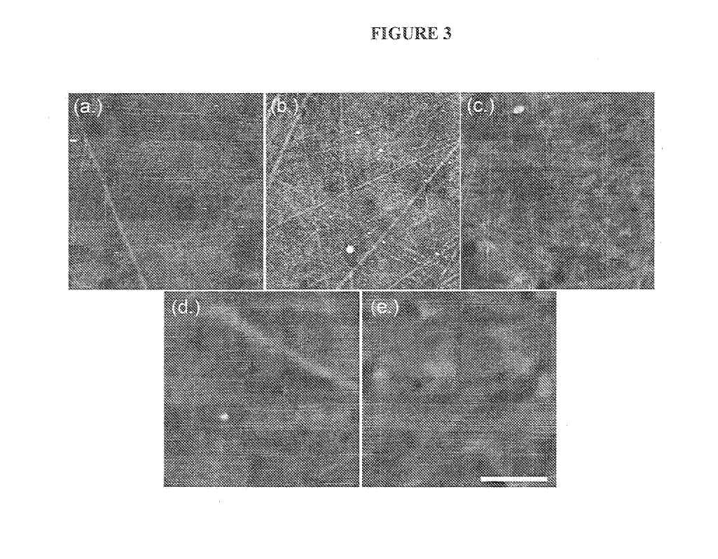

AFM was performed on the samples to rule out the possibility that the adhesion was improved simply by surface roughening after solvent exposure. A roughened surface would lead to a higher surface area and potentially more points of physical contact for the Cr to adhere to the underlying substrate. AFM scans were conducted on selected samples of each type using a Veeco Metrology Dimension 3100 AFM operating at room temperature. Samples were imaged using intermittent contact (Tapping Mode) using a Si cantilever (Olympus OTESPA) with a resonance frequency of about 300 kHz. Typical imaging conditions were to image a 30 μm×30 μm area at a scan rate of 0.5 Hz and 512 samples per line. FIG. 3 shows the 30 μm×30 μm AFM images for the control (3a), plasma-treated (3b), hexane-cast (3c), toluene-cast (3d) and chloroform-cast (3e) samples. From these images, there is little evidence that solvent exposure increased the surface roughness of the substrates. Measuring the root mean square roughness values (Rq) values for each of the images showed that the control sample had a Rq value of 2.8 nm which was nearly identical to all sample types (plasma=2.7 nm, hexane=2.7 nm, toluene 2.3 nm and chloroform=2.7 nm). The plasma-treated sample (FIG. 3b) exhibited a thin residue on the surface presumably due to redeposition of sputtered PMMA which, if anything, might account for the improved adhesion compared to the control sample. Clearly, surface roughness cannot account for the improvement in adhesion shown in FIG. 3 for the toluene and chloroform-treated samples.

### Example 2

### A. Sample Preparation

PMMA substrates (2.54 cm×2.54 cm) were cleaned by sonicating in 2-propanol (TPA) and prepared as previously described in Example 1. The spun-cast solvents tested from least to most polar were: hexanes (C₆H₁₄), carbon tetrachloride (CCl₄), toluene, chlorobenzene (C₆H₅Cl), dichloromethane (CH₂Cl₂), tetrahydrofuran (C₄H₈O) and CHCl₃. For all solvents, a subset of the samples were loaded into a vacuum chamber held at less than about 5×10⁻⁶ Torr for 96 hours to assure that the solvent had adequately desorbed from the surface prior to metallization. Metallization was accomplished by magnetron sputter deposition. A metal thin film of Cr having a thickness of about 10 Å was deposited first, followed by deposition of an Au film having a thickness of about 1000 Å in the same manner as described above with respect to Example 1.

Vapor exposed samples of chloroform, dichloromethane and hexane were also prepared. A chamber was designed consisting of a 10 inch diameter Petri dish covered by a sheet of 200 μm-thick polydimethylsiloxane (PDMS) film (Rogers Corp). 100 mL of solvent was placed in the Petri dish, and IPA cleaned PMMA chips were attached to the PDMS on the bottom side of the cover which was held by surface tension. The PDMS cover was sealed around the edge of the Petri dish and the samples were held in the chamber for times ranging from about 0 to about 10 minutes. Samples were then immediately loaded into the deposition chamber and metallized.

### B. Material characterization

Metal adhesion was determined by using a standard “tape test” measurement which was recorded using a digital camera and a stereo optical microscope. The digital images were converted to grayscale and measured using digital image processing software as described above with respect to Example 1.

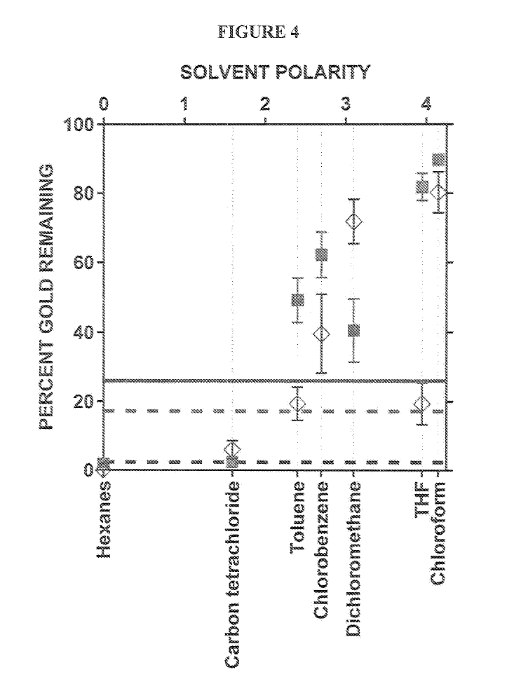

FIG. 4 illustrates the percent of Au remaining for each of the different types of spun-cast solvents as well as the IPA as-cleaned and remote O₂ plasma treated as controls with the solvents arranged in order of increasing solvent polarity index. For each type of solvent are shown the results of metal deposition immediately after spin-casting (within 10 minutes, solid squares in FIG. 4), and deposition after the samples had been held at less than about 5×10⁻⁶ Torr for 96 hours (open diamonds in FIG. 4). The dotted line at ˜19% Au remaining is for the control samples deposited within 10 min. after cleaning, and the dotted line at ˜2% Au remaining is for the control sample after the samples had been held at less than about 5×10⁻⁶ Torr for 96 hours. The solid line at ˜26% is the adhesion of the oxygen plasma treated control samples. Error bars are reported for each as one standard deviation from the mean value. As can be seen in FIG. 4, there are obviously significant differences in Cr/Au adhesion depending on the type of solvent, but several trends emerge. The first is that polar chlorinated solvents all exhibit improved adhesion compared to the as-cleaned control sample with the chloroform resulting in nearly 90% adhesion. Another trend concerns several sample types which either significantly improve or degrade after being held under vacuum. Specifically, THF initially has over 80% adhesion as-spun cast, but drops to 20% after vacuum exposure, while dichloromethane begins with 40% adhesion which improves to 70% adhesion after vacuum exposure. The non-chlorinated solvents exhibited the largest drop in Au adhesion after being held in vacuum, while the polar chlorinated solvents either exhibited either a modest drop (chloroform and chlorobenzene) or an improvement in Au adhesion (dichloromethane).

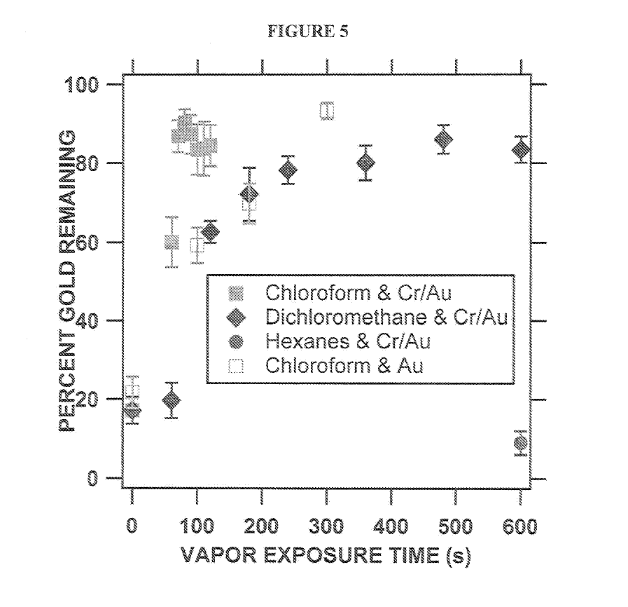

The tape-test results for the samples exposed to solvent vapors (as opposed to spun-cast in FIGS. 1-4) are illustrated in FIG. 5. In FIG. 5 solid symbols are used for Cr/Au metal thin films, and open symbols are used for Au only (no Cr adhesion layer). Both chloroform (solid and open squares) and dichloromethane (solid diamonds) exhibit the same adhesion improvement as spun-cast solvents suggesting that it is the chemistry of the solvent-polymer interaction that is critical, and the improvement is not due to an effect related to fluid dynamics, spin-casting, or the dissolution and resolidification of the polymer that might be caused by a liquid solvent interacting with the solid polymer surface. As with FIG. 4, samples exposed to hexane vapor (solid circles) in a similar fashion did not show any tendency to exhibit improved Cr/Au adhesion as shown in FIG. 5.

In order to better understand the vacuum results of FIG. 4, evolved gas analysis Fourier transform infrared spectroscopy (EGA-FTIR) was used to measure the chemical composition of evolved gases as solvent-treated PMMA samples were heated from a temperature of about 30° C. to a temperature of about 150° C. Samples for EGA-FTIR were prepared by cutting a 1.5 mm 1.5 mm grid array into the cleaned PMMA substrate using a CO₂ laser-cutter such that the depth of the cut was approximately 90% of the way through the PMMA solvent. Chloroform and dichloromethane were then each spun-cast onto the uncut surface, and five cubic pieces of each were carefully scored and placed into the 9 mm outer diameter resistively heated tube furnace.

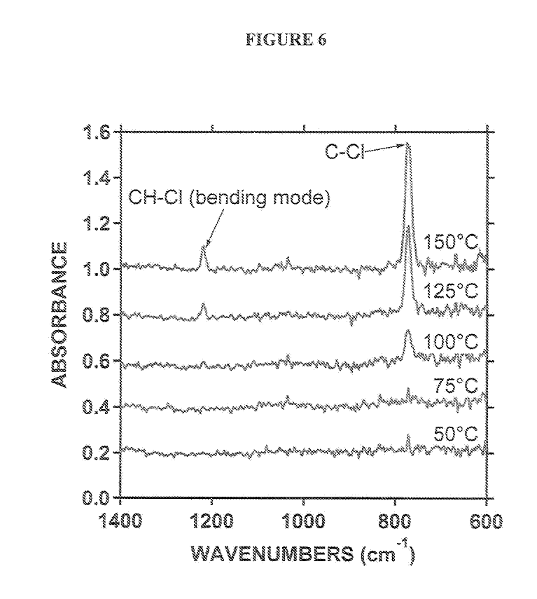

Waterfall plots for the EGA-FTIR at different temperatures are shown in FIG. 6 for the chloroform-treated sample, which shows that there are two peaks observed with peaks centered at 750 cm⁻¹ and between 1250-1300 cm⁻¹. These peaks correspond to the C—Cl stretching mode and the CH—Cl bending mode, respectively. As the temperature is increased to the decomposition temperature of PMMA, there is a monotonic increase in evolved gas intensity suggesting that the increasing temperature is desorbing excess chlorinated solvent out of the bulk PMMA. EGA-FTIR was measured with all solvents within 10 min. of solvent deposition, but no evolved gases were detected in any other solvents.

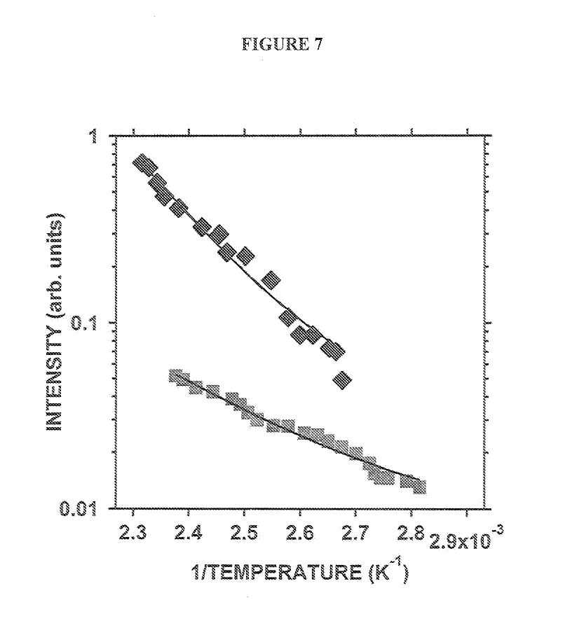

The area of the 750 cm⁻¹ C—Cl peak in the EGA-FTIR was calculated for the samples measured 9 days after spin-casting to ensure that the remaining bulk solvent had evaporated. A Van't Hoff plot was produced by plotting the natural log of the integrated peak intensity vs. the inverse temperature as shown in FIG. 7. The dark squares are data for dichloromethane and the light squares are for chloroform-treated samples. The slopes of FIG. 7 are directly proportional to the enthalpies of the solvent desorption process of chloroform (36.2 kJ/mol) and dichloromethane (63.8 kJ/mol).

A Thermo Scientific K-Alpha x-ray photoelectron spectroscopy (XPS) instrument was used for surface analysis. Samples that measured 1 cm×1 cm were mounted on a 6 cm×6 cm sample holder and introduced in the analysis chamber through a turbo-pumped load-lock system. Base pressure in the analysis chamber was 4.5×10¹⁰ Torr. The PMMA samples are insulators and therefore charged during XPS analysis. To alleviate the adverse effects of charging, the K-Alpha instrument uses a charge compensation system consisting of low energy Ar ions and low energy electrons. Pressure in the analysis changer was 1.5×10⁻¹⁰ Torr during charge compensation. A monochromatic Al K-alpha x-ray source (1486.7 eV) was focused to a 400 μm diameter spot on the sample surface to generate photoelectrons. A double focusing hemispherical energy analyzer was used to direct photoelectrons emitted at 90° from the sample plane onto a 128-channel detector. Survey scans were acquired at 1 eV/step at a pass of 200 eV, while high-resolution core level spectra were acquired at 0.1 eV/step and a pass energy of 50 eV. Data were acquired and analyzed using the Advantage Software package (v. 4.61).

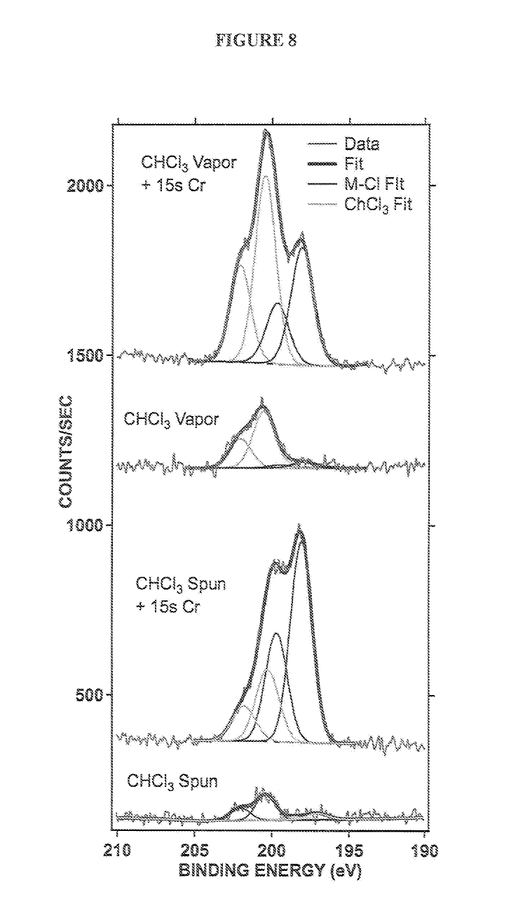

FIG. 8 shows data from high resolution XPS of the Cl 2p binding energy region from 190-210 eV for samples of spun-cast and vapor exposed PMMA. FIG. 8(a) shows a sample in which 10 Å of Cr was deposited onto a chloroform vapor-treated PMMA sample 24 h prior to XPS analysis. FIG. 8(b) shows chloroform vapor-exposed onto PMMA one day prior to loading into the XPS load lock. FIG. 8(c.) shows chloroform spun-cast PMMA with 10 Å of Cr deposited, and FIG. 8(d) shows PMMA with only spun-cast chloroform. A series of four peaks have been used to fit the XPS data for FIG. 8. In FIG. 8(a), the low binding energy peaks of 198.03 and 199.73 eV are the Cl 2p 3/2 and 1/2, respectively, of Cl bonded to a metal and are consistent with Cr—Cl bonding which has a known Cl 2p 3/2 binding energy of 197.8 eV. The higher binding energy peaks of 200.41 and 202.02 eV are characteristic of the Cl 2p 3/2 and 1/2, respectively, of C—Cl bonding which is consistent with the bonding present in polyvinylidene chloride with a Cl 2p 3/2 peak of 200.78 eV. In FIG. 8(b), the Cl peak is much less pronounced, and the low binding energy Cr—Cl peak, if present at all, is not distinguishable from the background signal, while the C—Cl bonding at 200.41 eV can be seen above the background.

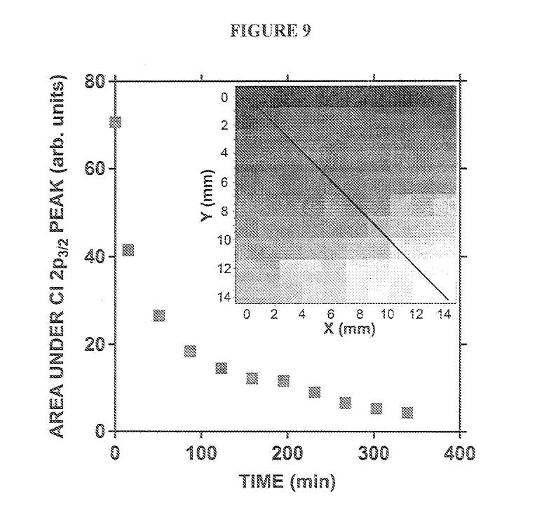

FIG. 9 shows the time evolution of the relative peak area of the Cl 2p peak for a CHCl₃-PMMA sample. This data was taken by focusing the x-ray to a 400 μm spot and analyzing only the Cl 2p region which took approximately 0.33 min. per pixel. The sample stage was then translated by 1.5 mm and the process was stepwise repeated overnight. The Cl 2p peak area was integrated at each pixel and plotted as the gray squares in FIG. 9. A 11×10 pixel intensity map of integrated pixels is shown in the inset of FIG. 9. The actual data points for FIG. 9 were generated by plotting each pixel along the indicated black solid line in the inset data. Not surprisingly, there is a significant drop in Cl 2p peak intensity with time as the solvent evaporates off of the surface, but is consistent with the EGA-FTIR results in FIGS. 6 and 7, indicating that there is Cl bonding present hours after spin-casting, while being maintained in an ultra high vacuum environment which should be more than sufficient to vaporize any residual solvent.

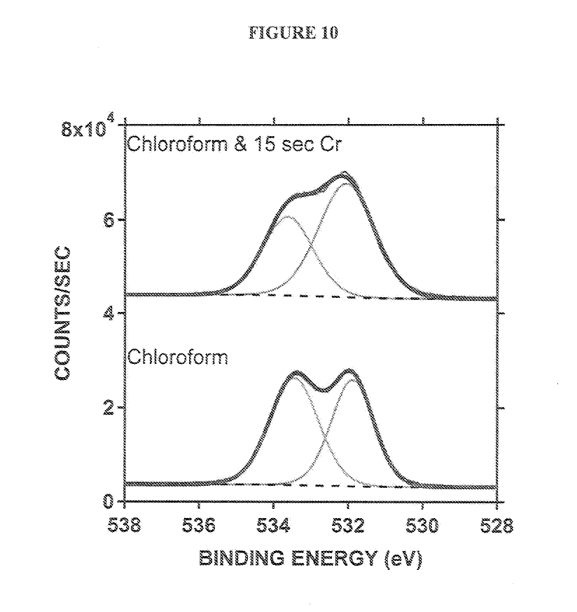

FIG. 10(a) shows high-resolution XPS data for the O 1s region of the Cr-chloroform treated PMMA sample, and FIG. 10(b) shows the as-spun-cast chloroform-treated PMMA sample. In FIG. 10(b), a doublet is observed which is well known for the two types of O bonding present in PMMA. The low binding energy peak has been assigned to C═O at a binding energy of 532.21 eV and the higher binding energy peak at 533.77 eV is due to the bridging O in the ester bond (—O—). We have observed this doublet for all solvent types, but FIG. 10(a) shows a suppression of the —O— peak, indicating that the Cr atom is interacting with the bridging O in the ester bond.

Chemical force microscopy (CFM) was used to measure the polar or non-polar nature of the PMMA samples before and after spin-casting chloroform or hexanes onto the surface. CFM measurements were performed on a Veeco Explorer microscope using μMasch DP17/LS probes (L=460 μm, k=0.15N/m, f₀=12 kHz). Prior to measurement, the AFM Probes were coated with a thin layer of Au and then a mercaptohexadecanoic acid (MHA) self-assembled monolayer was deposited onto the AFM probe by immersing the Au-coated probe into a 1 mM MHA solution in ethanol (EtOH) overnight, rinsed with EtOH and dried with N₂. This resulted in a highly polar AFM probe terminated with carboxylic acid functional groups. The MHA-coated probes were brought into contact with the PMMA surface with a feedback-controlled force of approximately 10 nN. The lateral force was measured by dragging the probe a few nm perpendicular to the AFM cantilever. The direction was then reversed and the tip traveled 500 nm. The direction was reversed again and the tip was returned to its original position. The lateral force signal is plotted as a function of the position of the probe to form a “friction loop”. The amplitude of this loop is proportional to the amount of friction between the probe and the surface. A commercial AFM control interface (3^{rd} Tech DP-100) was used to control the probe in a predefined trajectory. As the tip moved, lateral force, position and topography data were collected, and a 40 point box car average was applied to the lateral force data to smooth the molecular scale slip-stick motion of the tip.

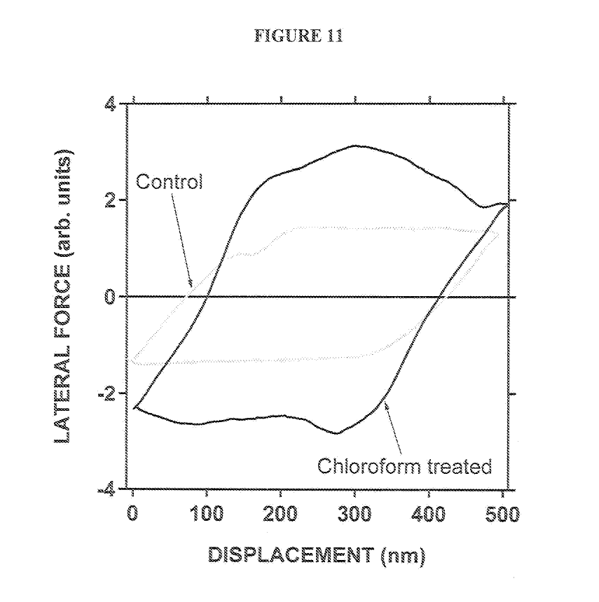

FIG. 11 shows representative data of the lateral force signal for the CFM study for chloroform-treated and as-cleaned PMMA samples. We were unable to obtain data for hexane-treated samples because the MHA-coated AFM probes did not engage on the highly hydrophobic surface of the hexane-treated samples. The chloroform-exposed samples exhibited nearly a factor of 2 higher friction loops indicating a much stronger probe-surface interaction between the carboxylic acid-terminated AFM probe as one would expect on a more polar surface. These measurements were repeated approximately 10 times alternating between chloroform and control samples, with similar results each time. The friction force data, while more indirect than the spectroscopic data, strongly suggests the presence of a highly polar residual surface chemistry after chloroform deposition and compliments the XPS and FTTR results.

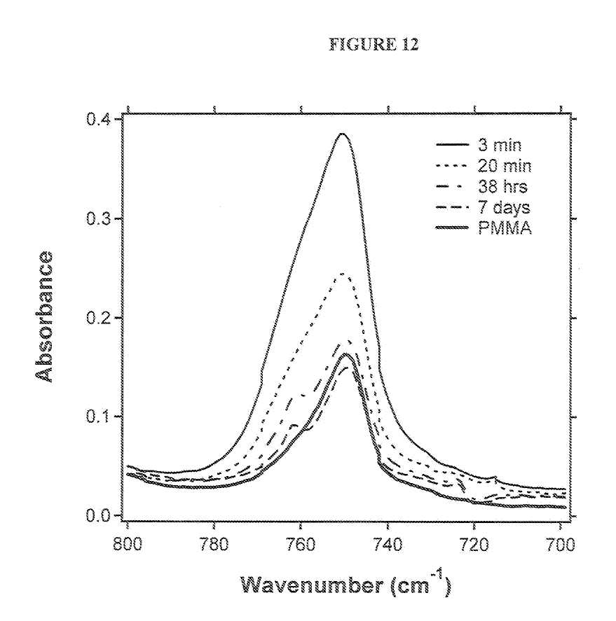

Without being bound by any particular theory, there are at least two possible mechanisms for the improved adhesion that can result from using methods of the present technology. A first theory is that the solvent may create a more polar oxygen-rich surface by preferentially orienting the ester groups in the PMMA chain towards the surface which results in bonding of the Cr metal to the ester oxygen atoms. A second theory relates to residual solvent molecules being present on the PMMA surface that may result in improved adhesion of the sputter-deposited Cr atoms. Spectroscopic evidence provided through attenuated total reflection Fourier transform infrared spectroscopy (ATR-FTIR) in which C—Cl bonding was observed up to 7 days after solvent deposition, shown in FIG. 12, discussed below, suggests that the second mechanism is more probable. The analytical evidence gathered in Example 2 indicates that that there is Cl bonding present through several complimentary techniques in as-spun-cast PMMA samples observed for several days after deposition. FIGS. 6-12 all provide evidence that even though chloroform has a moderate to low vapor pressure (195 Torr at 25° C.), it is present in measurable quantities both at the surface and in the bulk. The slope of the Van't Hoff plot in FIG. 7 yield an enthalpy of desorption from the PMMA of 36 kJ/mol and 64 kJ/mol for chloroform and dichloromethane, respectively. While it might initially appear that polar solvents are responsible for the enhanced adhesion, FIG. 4 shows that polarity alone is not sufficient to understand this phenomenon when considering the vacuum-stored samples.

The experimental data of Examples 1 and 2 may be best understood considering the non-complexing behavior of both chloroform and dichloromethane with PMMA in contrast to THF, carbon tetrachloride and hexane which are all considered complexing solvents. The terms “complexing” and “non-complexing” are used to describe the interaction between the solvent and the polymer chains in solution as understood by the formation of Lewis acid-base adducts between the solvent and the polymer chain. More specifically, the terms “complexing” and “non-complexing” refer to chain-chain interactions and not interaction between the solvent and polymer. A complexing solvent means that there is little or no Lewis acid-base interaction between the solvent and the polymer chain and the polymer chains themselves are able to form a complex in solution. In the case of PMMA, the polar ester groups would enable chain-to-chain dipole interactions which would form a polymer complex in solution. In a solvent categorized as non-complexing, the solvent and polymer interact through the formation of a Lewis acid-base adduct which minimizes interactions between chains. Specifically in the case of chloroform or dichloromethane and PMMA, the adduct is formed between a H on the solvent molecule acting as a Lewis acid and the O atoms in the ester group in PMMA acting as a Lewis base.

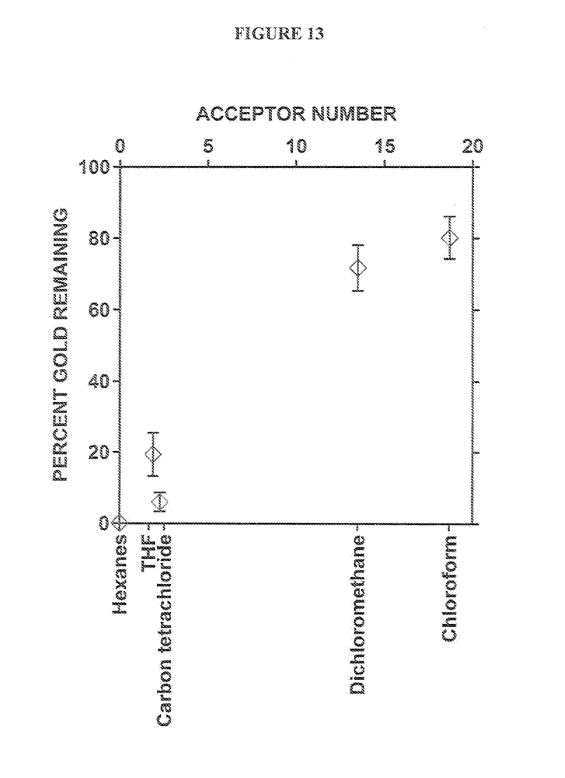

A parameter which quantifies Lewis acidity of a material has been defined called the Gutmann's acceptor number (AN). A large AN is indicative of a non-complexing solvent while a low AN is assigned to a complexing solvent. The AN is derived from. FIG. 13 shows the relationship between the measured percent Au adhesion and the literature values for the Gutmann's acceptor number which show a correlation between non-complexing solvents (larger number) and enhanced Cr/Au adhesion. This can be compared to FIG. 4 which shows the effect of Cr/Au adhesion on solvent polarity. For the Cr/Au samples deposited immediately after solvent deposition, there does appear to be a correlation of adhesion with solvent polarity index, but after vacuum storage, a polar but complexing solvent such as THF show significantly lower adhesion compared to the polar but non-complexing solvents such as chloroform and dichloromethane.

In the case of THF, while the solvent itself is highly polar, since it has not formed an adduct with the polymer chains, there is no spectroscopic evidence of residual solvent and thus no enhanced metal adhesion. In the case of the non-complexing solvents, XPS data in FIG. 8(a) clearly shows chemical bonding between Cr and the residual Cl present in the PMMA after solvent evaporation. It is this chemical bond that is responsible for the improved metal film adhesion.

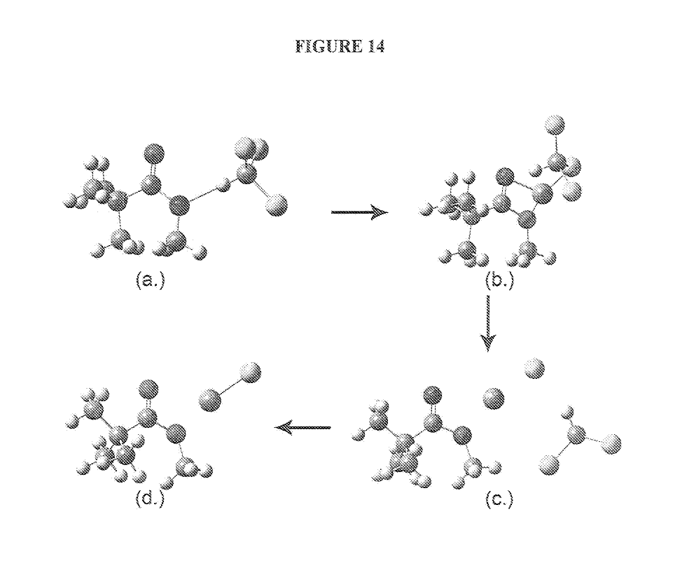

In order to better understand a molecular level cause for the enhanced metal adhesion, we have performed DFT calculations on a model of the PMMA/solvent/Cr system. The most energetically favored configuration was that in which the solvent molecules formed a complex in which the H on the solvent molecule aligned to the bridging O in a configuration typical of a hydrogen bond. Results of the DFT calculation are shown in FIG. 14.

Molecular modeling was accomplished using the Gaussian09 with GaussView 4.1.2 molecular modeling software to perform density functional theory calculations (DFT). DFT parameters used B3LYP with G-31G++ basis set calculations. The PMMA substrate was modeled with a methyl 2,2-dimethlypropanoate ((CH₃)₃CCO₂CH₃) molecule in order to capture the chemistry of the organic backbone and the ester group, but minimize the computational requirements in the DFT calculation. In addition to the substrate molecule, chloroform, dichloromethane and THF solvent molecules were independently examined. To determine the solvent-substrate interaction, the solvent and the ester group were initially aligned close to one another, and GaussView calculated to find a local minima. Several different starting positions for the solvents were considered including initially aligned with the C═O and aligned with the bridging O in the ester group. After the solvent molecule was minimized with the substrate molecule, a Cr atom was introduced and minimized. Calculated energies for this interaction were on the order of 35-42 kJ/mol consistent both with a hydrogen bonding-type interaction and with the EGA-FTIR results discussed in FIG. 7 above.

The desorption enthalpy of CH₂Cl₂ at first glance appears anomalous as the enthalpy estimated from EGA-FTIR is nearly double that of CHCl₃. Intuitively, the CHCl₃ should exhibit a stronger hydrogen bonding, interaction with the ester O atoms due to the increased electronegativity of having three Cl atoms rather than two. However, when one considers that CH₂Cl₂ can form two hydrogen bonds, then the interaction per bond is approximately 32 kJ/mol, which is consistent with both the polarity trend and with the DFT calculation.

FIG. 14(a) suggests that the chloroform molecule interacts more strongly with the bridging O compared to the C═O. This calculation is also consistent with the XPS data for the O 1s peak show in FIG. 10. PMMA has a well-known O 1s doublet corresponding to the bridging O which has a binding energy of 533.77 eV while the C═O has a binding energy of 532.21 eV. FIG. 14(a) shows that the higher binding energy peak at 534 eV is suppressed in the Cr-coated sample compared to the CHCl₃ treated-sample shown in FIG. 14(b). This would indicate that when the Cr atom interacts with the Cl, there is a change in the local bonding environment in the bridging O atom. The higher binding energy of the bridging O in PMMA indicates that it is more electronegative and this would be more likely to exhibit a dipole-dipole interaction with the positive dipole of the chlorinated solvent molecules which is also confirmed by DFT.

After the solvent-PMMA calculation had minimized (FIG. 14(a)), a Cr atom was introduced into the DFT model and allowed to minimize. In each different starting configuration that was chosen, an interesting phenomenon was predicted by DFT with regards to the Cr interaction. Namely, the Cr atom inserted itself between the Cl—C bond in the solvent as shown in FIG. 14(b). This was followed by the same Cl—C bond in the solvent breaking and the remainder of the solvent (either HCCl₂ for chloroform or H₂CCl for dichloromethane) desorbing (FIG. 14(c)) leaving behind a bonding interaction of O—Cr—Cl as shown in FIG. 4d).

The resulting O—Cr—Cl bonding configuration at the surface would result in electron density being removed from the Cr due to the electronegativity of the Cl atom, thus resulting in a more electropositive Cr—O interaction which explains the enhanced stability of the Cr—O bonding at the surface. A subsequent Cr atom arriving during the sputter deposition process would now see a surface that has a Cl atom bonded to another Cr which can form an energetically favorable Cr—Cl bond which is also consistent with the Cr—Cl bonding peak clearly evident in FIG. 8(a).

While the actual energy numbers calculated from the DFT calculation are at best an approximation, several results are striking. The results of the DFT modeling are entirely consistent with all of the reported experimental data. Namely: (1.) the preferred interaction between the Cr and the bridging O is consistent with the suppression of the high binding energy O 1s peak in the XPS data as shown in FIG. 10; (2.) the molecular modeling accounts for the presence of residual solvent molecule interacting with a similar energy to a hydrogen bond which is consistent with the spectroscopic data shown and with the known Lewis acid-base adduct formation in non-complexing solvents with PMMA; and (3.) the interaction energies calculated by DFT have similar trends and energies compared to the EGA-FITR data shown in FIG. 6.

Without being bound by any particular theory, a three step model based on DFT-B3LYP-6-32G++ calculations for model systems has been developed to explain the increased binding of metals to polymeric surfaces. Initially, the hydrohalocarbon forms a non-traditional hydrogen bond to an oxygen in the ester group. While this bond is calculated to be <50 kJ/mol, the experimental evidence indicates that it is strong enough to keep the hydrohalocarbon on the surface for times ranging from a few hours to days. The metal atoms being deposited react with the surface adsorbed hydrohalocarbon to form the metal chloride and chlorinated organic products during the second step of the model. Assuming the rate limiting, stem in this process is the transfer of a chlorine atom from the hydrochlorocarbon to the metal,

M+CHₓCl_{y}—Cl [symbol] M-Cl+CHₓCl_{y} 1.

Assuming ΔS is approximately zero, the Gibbs Energy for this process is approximately equal to ΔᵣH which can be estimated as the difference in the M-Cl and CHₓCl_{y}—Cl bond formation energies.

ΔG-BE(M-Cl)-BE(CHₓCl_{y}—Cl) 2.

The exact CHₓCl_{y}—Cl bond energy depends upon the compound and the bond being broken, but 338 kJ/mol, the gas phase value for CHCl₂—Cl, is a reasonable estimate. This suggests that any metal with a M-Cl bond>338 kJ/mol will form the metal chloride from reaction 1. The third step of the model is the interaction between the metal chloride formed and the oxygen on the polymer surface (Sur).

MCl+Sur [symbol] Sur-MCl 3.

The partial positive charge on the metal in the metal chloride is expected to produce a stronger bond to the surface leading to the increased binding for most metals. For example, model calculations using methyl acetate (MA) to represent the surface ester groups indicated that the surface binding, went from 30 kJ/mol for iron bound to MA to 174 kJ/mole when iron chloride was bound. Similar calculations for copper indicated an increase from 22 kJ/mol for metal to 145 kJ/mol for copper chloride. Any metal that will react with the hydrochlorocarbon to form the metal chloride and for which the metal chloride binds more tightly to the surface than the metal will show enhanced adhesion to the surface.

This bonding model suggests that other similar halogenated solvents including F, Br, and I should exhibit similar chemistry with fluorinated solvents required a stronger M—Cl bond and Br and I solvents enabling a weaker M-Cl bond since the bond dissociation energies of the CHX₂—X compound where X═F, Br and I are 465, 275 and 239 kJ/mol, respectively.

Since different hydrohalocarbons exhibit different chemical bond strengths, one can tailor the surface properties of the adhesion strength depending on the hydrohalocarbon employed. For example, CHF₂Br will exhibit a strong Lewis acid-base adduct with the surface of PMMA due to the highly electronegative F atoms, but the Br atom will act as a leaving group and results in the metal adhesion to the surface.

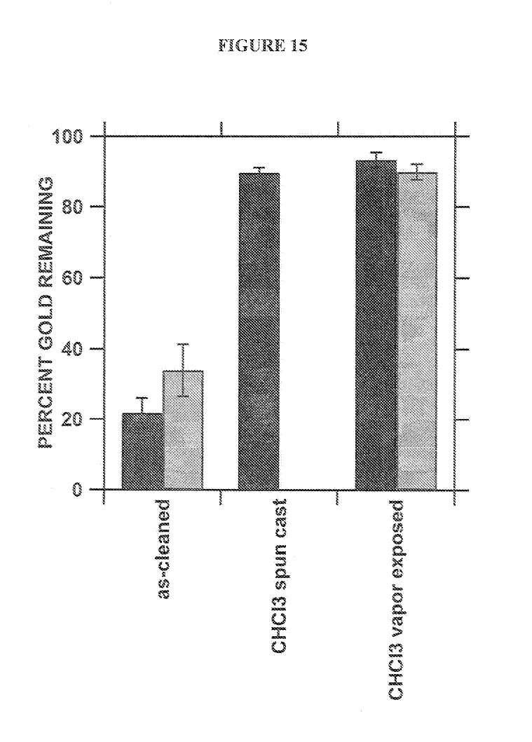

In addition to magnetron sputtering deposition, it has been shown that Au deposited via electron beam evaporation using a CHCl₃ adhesion promoter are just as effective. FIG. 15 shows the results comparing spun-cast vs. vapor exposed chloroform adhesion promoter for magnetron sputter deposited (black) and e-beam evaporated (gray) Au films onto PMMA. The control sample is also shown for each deposition type. This suggests that other metal vapor deposition techniques such as atomic layer deposition, chemical vapor deposition, thermal evaporation, molecular beam epitaxy, etc. should be effective in depositing metal onto the surface of PMMA using the non-complexing solvent adhesion promoter. In addition, electrodeposition and electroless deposition should be amenable to this process.

The ability to deposit Au films directly onto polymeric substrates enables the use of self-assembled monolayer technology using thiol-based chemistry to engineer the surface chemistry of polymeric substrates in a facile manner.

From the foregoing, it will be appreciated that although specific examples have been described herein for purposes of illustration, various modifications may be made without deviating from the spirit or scope of this disclosure. It is therefore intended that the foregoing detailed description be regarded as illustrative rather than limiting, and that it be understood that it is the following claims, including all equivalents, that are intended to particularly point out and distinctly claim the claimed subject matter.

What is claimed is:

1. A method of forming a deposited metal film on a polymeric substrate, comprising:
depositing one or more layers of metal onto a polymeric substrate; and
contacting the polymeric substrate with a non-complexing solvent either before or after the depositing.

2. The method of claim 1, wherein the polymeric substrate includes acrylic polymers, polyethylene, polypropylene, and/or polystyrene.

3. The method of claim 2, wherein the polymeric substrate is an acrylic polymer.

4. The method of claim 3, wherein the acrylic polymer includes poly(methyl methacrylate) (PMMA), poly acrylic acid (PAA), poly(n-butyl methacrylate) (p(nBMA)), poly(tert-butyl methacrylate) (p(tBMA)), poly(allyl alcohol), poly(hydroxyethyl acrylate), and/or polyimides.

5. The method of claim 1, wherein the contacting of the polymeric substrate with a non-complexing solvent includes spin casting, vapor exposure, spray exposure, jet nebulizer, ultrasonic wave nebulizer, or dip coating.

6. The method of claim 1, wherein the non-complexing solvent includes chloroform, dichloromethane, bromoform, or another hydrohalocarbon.

7. The method of claim 1, wherein the metal is deposited onto the substrate by vapor deposition, electroplating, or electroless plating.

8. The method of claim 7, wherein the method of vapor deposition is selected from the group consisting of magnetron sputter deposition, chemical vapor deposition, e-beam evaporation, thermal evaporation, molecular beam epitaxy, and atomic layer deposition.

9. The method of claim 1, wherein the depositing of one or more layers of metal onto the substrate comprises:
depositing a first metal layer as an adhesion layer onto the polymeric substrate; and
depositing a second metal layer onto the adhesion layer.

10. The method of claim 1, wherein the depositing of one or more layers of metal onto the substrate consists of:
depositing a single layer of metal directly onto the polymeric substrate.

11. The method of claim 10, wherein the single layer of metal comprises Cr, Cu, Ag, Au, Mo, W, Mn, Fe, Co, Ni, Pt, V, Ti, Zr, Hf, Ta, or Nb.

12. The method of claim 1, wherein the polymeric substrate comprises polymeric fibers.

13. The method of claim 1, wherein the polymeric substrate is non-planar.

14. The method of claim 1, wherein the step of contacting the polymeric substrate with a non-complexing solvent includes applying a spatially defined pattern of the solvent to the substrate.

15. The method of claim 14, wherein metal deposited onto areas of the substrate outside the pattern of solvent are removed.

16. The method of claim 1, further comprising the step of:
exposing the one or more layers of metal to a molecule that forms a self-assembled monolayer on the surface of the one or more layers of metal.

17. The method of claim 1 wherein the contacting occurs before the depositing.

18. The method of claim 1 wherein the depositing occurs before the contacting.

19. The method of claim 18 wherein the depositing includes depositing a single layer of Au.

20. The method of claim 19 wherein the Au layer is 15 nm or less thick.

21. The method of claim 18 wherein the contacting includes contacting the substrate with halogenated solvent vapor.

22. A method of forming a deposited metal film on a polymeric substrate, comprising:
depositing one or more layers of metal onto an acrylic polymer substrate; and
contacting the substrate with a non-complexing solvent either before or after the depositing.

23. The method of claim 22, wherein the acrylic polymer includes PMMA.

24. The method of claim 22, wherein the non-complexing solvent includes chloroform, dichloromethane, bromoform, or another hydrohalocarbon.

25. The method of claim 22, wherein the depositing of one or more layers of metal onto the substrate comprises:
depositing a first metal layer as an adhesion layer onto the polymeric substrate; and
depositing a second metal layer onto the adhesion layer.

26. The method of claim 25, wherein the adhesion layer comprises Cr.

27. The method of claim 25, wherein the second layer comprises Cr, Cu, Ag, Au, Mo, W, Mn, Fe, Co, Ni, Pt, V, Ti, Zr, Hf, Ta, or Nb.

28. The method of claim 22, wherein the depositing of one or more layers of metal onto the substrate consists of:
depositing a single layer of metal directly onto the polymeric substrate.

29. The method of claim 28, wherein the single layer of metal comprises Cr, Cu, Ag, Au, Mo, W, Mn, Fe, Co, Ni, Pt, V, Ti, Zr, Hf, Ta, or Nb.

30. The method of claim 22 wherein the contacting occurs before the depositing.

31. The method of claim 22 wherein the depositing occurs before the contacting.

32. The method of claim 31 wherein the depositing includes depositing a single layer of Au.

33. The method of claim 32 wherein the Au layer is 15 nm or less thick.

34. The method of claim 31 wherein the contacting includes contacting the substrate with chloroform vapor.
